(19) United States
(12) Patent Application Publication
(10) Pub. No.: US 2026/0177640 A1
(43) Pub. Date: Jun. 25, 2026

(54) METHOD AND APPARATUS FOR INSPECTING INTERNAL SHORT IN BATTERY CELL AND MEASUREMENT BATTERY CELL

(71) Applicant: SK On Co., Ltd., Seoul (KR)

(72) Inventors: Tae Gyun YU, Daejeon (KR); Jung Hyun SEO, Daejeon (KR); Kyeong Min LEE, Daejeon (KR); June Sun HWANG, Daejeon (KR)

(21) Appl. No.: 19/424,157

(22) Filed: Dec. 18, 2025

(30) Foreign Application Priority Data
Dec. 20, 2024 (KR) 10-2024-0192245

(51) Int. Cl. G01R 31/52; G01K 7/22; G01R 31/374; G01R 31/3842; G01R 31/396

(52) U.S. Cl. CPC G01R 31/52; G01K 7/22; G01R 31/374; G01R 31/3842; G01R 31/396

(57) ABSTRACT

A method for inspecting an internal short in a battery cell is disclosed. In some implementations, the method includes: forming a state in which a short-circuit current in the battery cell increases through an external circuit of the battery cell connected to a measurement electrode, with inserting a portion of the measurement electrode into the battery cell through an outer member of the battery cell; and measuring the short-circuit current through the external circuit.

### CROSS-REFERENCE TO RELATED APPLICATION(S)

This patent document claims the priority and benefits of Korean Patent Application No. 10-2024-0192245 filed on Dec. 20, 2024, the disclosure of which is incorporated herein by reference in its entirety.

### TECHNICAL FIELD

The disclosure and implementations disclosed in this patent document generally relate to a method and an apparatus for inspecting an internal short in a battery cell and a measurement battery cell.

### BACKGROUND

In a battery, unlike a primary battery, a secondary battery has convenience, in that the secondary battery is chargeable and dischargeable, and therefore has been in the spotlight as a power source for various mobile devices, electric vehicles, and the like. The secondary battery may include a battery cell in which an electrode assembly is accommodated inside a case, the electrode assembly being formed by stacking or winding a positive electrode plate, a negative electrode plate, and a separator in roll form. The battery cell may be included in a battery module, a battery pack, or a battery rack by stacking a plurality of battery cells in a predetermined direction. The battery pack or the battery rack may include a plurality of battery modules.

If even one of the plurality of battery cells included in the battery module, the battery pack, or the battery rack does not have guaranteed safety, the safety of the entirety of the plurality of battery cells may not be ensured. Therefore, the safety of the battery cell may be important, and various studies have been conducted on a technology for detecting a defect occurring in the battery cell.

When a defect occurs during a manufacturing process, when a battery cell is used for a long period in a harsh environment, when a lifetime of the battery cell is exhausted, or when an external impact is applied to the battery cell, an internal short may occur in the battery cell. The internal short in the battery cell may result in a short-circuit current in the battery cell, the short-circuit current may further deteriorate a state of the battery cell, and the short-circuit current in the deteriorated battery cell may become more severe. In this way, a battery cell in which the short-circuit current gradually increases may encounter a serious safety problem such as thermal runaway or destruction.

Therefore, inspecting an internal short in a battery cell may be important for ensuring the safety of the battery cell. Conventionally, to inspect an internal short in a battery cell, a method for simulating a specific situation has been performed, such as penetrating the battery cell with a nail or applying an impact (or a pressure) to the battery cell. However, such a method may cause inspection condition deviations (e.g., penetration depth and size deviation) among a plurality of battery cells, and may have difficulty in securing reliability of an internal short inspection of the battery cell.

### SUMMARY

The present disclosure may be implemented in some embodiments to provide a method and an apparatus for inspecting an internal short in a battery cell and a measurement battery cell, which may reduce inspection condition deviations among a plurality of battery cells, thereby improving reliability of an internal short inspection of the battery cell.

In some embodiments of the present disclosure, a method for inspecting an internal short in a battery cell includes: forming a state in which a short-circuit current in the battery cell increases through an external circuit of the battery cell connected to a measurement electrode, with inserting a portion of the measurement electrode into the battery cell through an outer member of the battery cell; and measuring the short-circuit current through the external circuit.

The external circuit may include a thermistor or a bimetal, and the forming of the state may include changing a temperature of the thermistor or the bimetal.

The external circuit may include a semiconductor device, and the forming of the state may include applying external power to the semiconductor device.

The forming of the state may include connecting a wire to a connector disposed on an electrode lead of the battery cell and the measurement electrode.

The battery cell may include an encapsulating member encapsulating at least one of the connector or the measurement electrode, and the forming of the state may include inserting the wire into the encapsulating member or removing a portion of the encapsulating member, so as to connect the wire to the connector and the measurement electrode.

The forming of the state may include connecting the external circuit between the measurement electrode connected to an outermost negative electrode plate among a plurality of negative electrode plates of the battery cell and an electrode lead of the battery cell connected to a positive electrode plate of the battery cell.

The method may further include: providing the battery cell by inserting a portion of the measurement electrode into the battery cell to have a portion of the measurement electrode overlapping a positive electrode plate and a negative electrode plate in a direction in which the positive electrode plate and negative electrode plate of the battery cell face each other.

The measuring may include generating short-circuit current evaluation information of the battery cell based on a difference between a pattern of the measured short-circuit current and a reference pattern.

In some embodiments of the present disclosure, a measurement battery cell includes: an outer member; a positive electrode plate accommodated in the outer member; a negative electrode plate accommodated in the outer member; a separator disposed between the positive electrode plate and the negative electrode plate; an electrode lead connected to one of the positive electrode plate and the negative electrode plate and protruding from the outer member; and a measurement electrode penetrating the outer member to have a portion thereof overlapping the positive electrode plate and the negative electrode plate in a direction in which the positive electrode plate and the negative electrode plate face each other.

The measurement electrode may be connected to only one of the positive electrode plate and the negative electrode plate.

The negative electrode plate may be provided as a plurality of negative electrode plates, the measurement electrode may be connected to an outermost negative electrode plate among a plurality of negative electrode plates, and the electrode lead may be connected to the positive electrode plate.

The measurement battery cell may further include: an encapsulating member encapsulating the measurement electrode.

The measurement battery cell may further include: a connector disposed on the electrode lead and encapsulated by the encapsulating member.

The measurement battery cell may further include a wire connected to the electrode lead or the measurement electrode.

In some embodiments of the present disclosure, an apparatus for inspecting an internal short in a battery cell includes: a measuring instrument for measuring a short-circuit current between the positive electrode plate and negative electrode plate of the measurement battery cell through a measurement electrode; a wire connected to the electrode lead of the measurement battery cell and measurement electrode; and an external circuit electrically connected between the electrode lead and the measurement electrode through the wire.

The measurement battery cell may include: an outer member; the positive electrode plate accommodated in the outer member; the negative electrode plate accommodated in the outer member; a separator disposed between the positive electrode plate and the negative electrode plate; the electrode lead connected to one of the positive electrode plate and the negative electrode plate and protruding from the outer member; and the measurement electrode penetrating the outer member to have a portion thereof overlapping the positive electrode plate and the negative electrode plate in a direction in which the positive electrode plate and the negative electrode plate face each other.

The measurement electrode may be connected to only one of the positive electrode plate and the negative electrode plate.

The negative electrode plate may be provided as a plurality of negative electrode plates, the measurement electrode may be connected to an outermost negative electrode plate among a plurality of negative electrode plates, and the electrode lead may be connected to the positive electrode plate.

The measurement battery cell may further include an encapsulating member encapsulating the measurement electrode.

The measurement battery cell may further include a connector disposed on the electrode lead and encapsulated by the encapsulating member.

The external circuit may include at least one of a thermistor, a bimetal, or a metal-oxide-semiconductor field-effect transistor (MOSFET).

### BRIEF DESCRIPTION OF DRAWINGS

Certain aspects, features, and advantages of the present disclosure are illustrated by the following detailed description with reference to the accompanying drawings.

FIG. 1 is a flowchart illustrating a method for inspecting an internal short in a battery cell according to an embodiment of the present disclosure.

FIG. 2A is a diagram illustrating the method for inspecting an internal short in a battery cell that inspects an internal short in the battery cell and an apparatus for inspecting an internal short in a battery cell according to an embodiment of the present disclosure.

FIG. 2B is a diagram illustrating a measurement battery cell according to an embodiment of the present disclosure.

FIGS. 3A and 3B are diagrams illustrating the method and the apparatus for inspecting an internal short in a battery cell and an interior of a battery cell into which a measurement electrode of a measurement battery cell is inserted, according to an embodiment of the present disclosure.

FIGS. 4A and 4B are diagrams illustrating the method and the apparatus for inspecting an internal short in a battery cell and a semiconductor device that may be included in an external battery cell, according to an embodiment of the present disclosure.

FIG. 5 is a flowchart more specifically illustrating the method for inspecting an internal short in a battery cell according to an embodiment of the present disclosure.

FIG. 6 is a graph illustrating the method and the apparatus for inspecting an internal short in a battery cell and a voltage and a temperature according to a time flow of the measurement battery cell, according to an embodiment of the present disclosure.

### DETAILED DESCRIPTION

Features of the present disclosure disclosed in this patent document are described by example embodiments with reference to the accompanying drawings.

The present disclosure may be implemented in some embodiments to provide a method and an apparatus for determining an internal short in a battery cell and a measurement battery cell.

Prior to providing a detailed description of the embodiments, it should not be construed that terms or words used in the following description and claims are limited to ordinary or dictionary meanings, and words used in the following description and claims should be interpreted as having meanings and concepts conforming to the technical spirit of the present disclosure based on the principle that an inventor may properly define the concepts of terms to describe the inventor's invention by using the best method.

The same reference numerals or symbols described or illustrated in each drawing denote parts or components that perform substantially the same functions. For convenience of description and understanding, the same reference numerals or symbols may be used for description even in different embodiments.

In the following description, a term of a singular number includes its plural number unless clearly indicated otherwise in the context. Terms such as “include” or “comprise” are intended to specify the presence of features, numbers, processes, operations, components, parts, or combinations thereof described in the specification, and are not intended to preclude the possibility of presence or addition of one or more other features, numbers, processes, operations, components, parts, or combinations thereof.

In addition, in the following description, expressions such as upper side, upper portion, lower side, lower portion, side, front, and rear are expressed based on the directions illustrated in the drawings, and it is previously stated that such an expression may be expressed differently if a direction of the corresponding subject is changed.

In addition, in the following description and claims, terms including ordinals such as “first” and “second” may be used for distinction among components. Such ordinals are used to distinguish the same or similar components from each other, and should not be construed to limit meanings of terms due to the use of such ordinals. For example, components coupled with such ordinals should not be construed as being limited in use order or arrangement order by the numerals. If necessary, the respective ordinals may be interchanged and used.

Hereinafter, the present disclosure is described in detail with reference to the drawings. However, the present disclosure is merely illustrative, and is not limited to the specific embodiments illustratively described. For example, although a pouch-type battery cell is described below, the type of the battery cell (e.g., a cylindrical battery module or a prismatic battery module) is not limited to the pouch type, and a specific form of the pouch type may also vary depending on design.

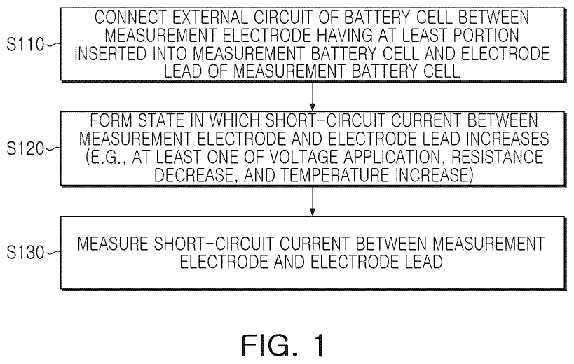

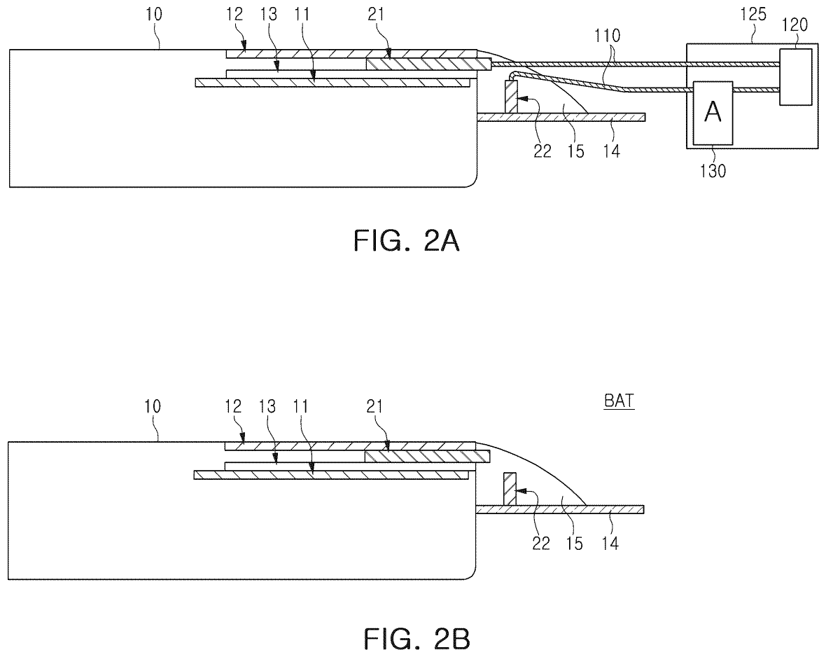

Referring to FIGS. 1, 2A, and 2B, a method for inspecting an internal short in a battery cell according to an embodiment of the present disclosure may include: forming a state (for example, at least one of voltage application, resistance decrease, and temperature increase) in which a short-circuit current in the battery cell (BAT) increases through an external circuit 125 of the battery cell (BAT) connected (S110) to a measurement electrode 21 having a portion inserted into the battery cell (BAT) through an outer member 10 of the battery cell (BAT) (S120); and measuring the short-circuit current through the external circuit 125 (S130).

A state of the battery cell (BAT) may include a first state in which the measurement electrode 21 is not inserted into the battery cell (BAT), a second state in which a portion of the measurement electrode 21 is inserted into the battery cell (BAT), and a third state in which the short-circuit current in the battery cell (BAT) increases from the second state. The short-circuit current in the battery cell (BAT) in the first and second states may be substantially absent, and the short-circuit current in the battery cell (BAT) in the third state may be large.

Inspection condition deviations among the plurality of battery cells may increase when a path through which the short-circuit current flows in each of a plurality of battery cells is physically and directly formed. However, in the method for inspecting an internal short in a battery cell according to an embodiment of the present disclosure, the insertion of the measurement electrode 21 into the battery cell (BAT) may form a state (the second state) favorable for increasing the short-circuit current in the battery cell (BAT) rather than directly causing the short-circuit current in the battery cell (BAT), thereby reducing the inspection condition deviations among the plurality of battery cells. In addition, the inspection condition deviations among the plurality of battery cells during a progress from the second state to the third state may also be reduced. The method for inspecting an internal short in a battery cell may reduce the inspection condition deviations among the plurality of battery cells, thereby improving reliability (and/or objectivity) of internal short inspection of the battery cell.

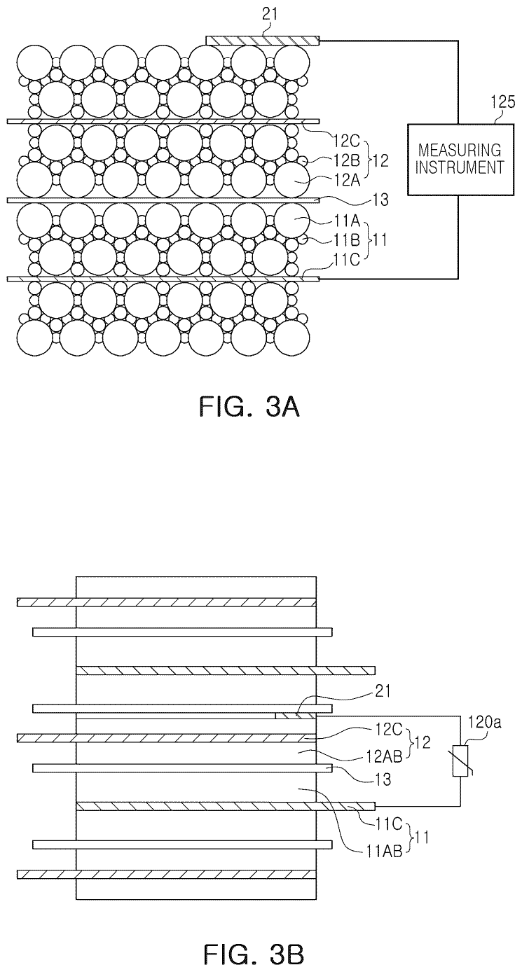

Referring to FIGS. 2B, 3A, and 3B, the measurement battery cell (BAT) according to an embodiment of the present disclosure may include: the outer member 10; a positive electrode plate 11C accommodated in the outer member 10; a negative electrode plate 12C accommodated in the outer member 10; a separator 13 disposed between the positive electrode plate 11C and the negative electrode plate 12C; an electrode lead 14 connected to one of the positive electrode plate 11C and the negative electrode plate 12C and protruding from the outer member 10; and a measurement electrode 21 penetrating the outer member 10 to have a portion thereof overlapping the positive electrode plate 11C and the negative electrode plate 12C in a direction (e.g., a vertical direction) in which the positive electrode plate 11C and the negative electrode plate 12C face each other. Accordingly, the inspection condition deviations among the plurality of measurement battery cells BAT may be reduced, thereby further improving the reliability and/or objectivity of internal short inspection of the battery cell.

The outer member 10 may have an internal space in which a positive electrode 11, a negative electrode 12, and an electrolyte are disposed, and the battery cell may be provided as a pouch-type battery including a sealing portion disposed at an edge of the outer member 10 and sealing the internal space. However, the configuration of the battery cell is not limited thereto. The separator 13 may prevent electrical short-circuit occurring between the positive electrode plate 11C and the negative electrode plate 12C and allow an ion flow. For example, the separator 13 may include a porous polymer film or a porous nonwoven fabric. The electrode lead 14 may include a first electrode lead electrically connected to the positive electrode 11 and a second electrode lead electrically connected to the negative electrode 12. The first electrode lead and the second electrode lead may protrude in the same direction or in opposite directions, and are not limited thereto.

The positive electrode 11 and the negative electrode 12 may be accommodated in the outer member 10 in various types such as a jelly-roll type formed by being wound in a predetermined direction, a stacking type, a Z-folding type, and a stack-folding type.

The positive electrode 11 may include the positive electrode plate 11C and a positive active material layer 11AB, and the negative electrode 12 may include the negative electrode plate 12C and a negative active material layer 12AB. The positive active material layer 11AB may include a positive active material 11A and a conductive material 11B, and the negative active material layer 12AB may include a negative active material 12A and a binder 12B.

For example, the measurement electrode 21 may not be physically connected to one of the positive electrode plate 11C and the negative electrode plate 12C, and may be connected to the other of the positive electrode plate 11C and the negative electrode plate 12C. That is, the insertion of the measurement electrode 21 into the battery cell (BAT) may not directly cause the short-circuit current in the battery cell (BAT), but may form a state (the second state) favorable for increasing the short-circuit current in the battery cell (BAT).

For example, the negative electrode plate 12C may be provided as a plurality of negative electrode plates 12C, and the measurement electrode 21 may be connected to the outermost negative electrode plate among a plurality of negative electrode plates 12C (e.g., the topmost negative electrode plate), and the electrode lead 14 may be connected to the positive electrode plate 11C. For example, the forming of the state may include connecting the external circuit 125 between the measurement electrode 21 connected to the outermost one (e.g., the topmost negative electrode plate) among the plurality of negative electrode plates 12C of the battery cell (BAT) and the electrode lead 14 of the battery cell (BAT) connected to the positive electrode plate 11C of the battery cell (BAT) (S110). Accordingly, an inspection range (e.g., number of target negative/positive electrode plates) of the short-circuit current in the battery cell (BAT) may be further broadened, and confusion in an insertion position (e.g., a position corresponding to the topmost negative electrode plate) of the measurement electrode 21 in the battery cell (BAT) may be stably prevented.

For example, the measurement battery cell (BAT) may further include an encapsulating member 15 for encapsulating the measurement electrode 21. For example, the battery cell (BAT) may include the encapsulating member 15 for encapsulating a connector 22 and the measurement electrode 21, and the forming of the state may include inserting a wire 110 into the encapsulating member 15 or removing a portion of the encapsulating member 15 to connect the wire 110 to the connector 22 and the measurement electrode 21. The encapsulating member 15 may protect the connector 22 and/or the measurement electrode 21 to thus reduce external influences (e.g., a lapse of waiting time, environmental changes, and impacts during transfer of the battery cell) from a state in which the measurement electrode 21 is inserted into the battery cell (BAT) to a state in which the short-circuit current in the battery cell (BAT) increases, thereby further improving the reliability and/or objectivity of internal short inspection of the battery cell. For example, the encapsulating member 15 may be implemented as an insulating material for heat fusion or may include a molding material.

Referring to FIGS. 2A and 2B, the measurement battery cell (BAT) may further include the connector 22 disposed on the electrode lead 14 and encapsulated by the encapsulating member 15, and may further include the wire 110 connected to the electrode lead 14 and the measurement electrode 21. For example, the forming of the state may include connecting the wire 110 to the connector 22 disposed on the electrode lead 14 of the battery cell (BAT) and the measurement electrode 21 (S110). Accordingly, a deviation in a connection point (and/or a connection state) of the wire 110 for each of the plurality of battery cells may be reduced, thereby further improving the reliability and/or objectivity of internal short inspection of the battery cell. For example, the wire 110 may be implemented as a power cable. For example, the connector 22 may have a structure that may be coupled to a power cable, may be electrically connected (e.g., welded) to the electrode lead 14, and may be erected on one point of the electrode lead 14.

For example, the measurement battery cell (BAT) may further include the external circuit 125 electrically connected between the electrode lead 14 and the measurement electrode 21 through the wire 110, and the external circuit 125 may include at least one device 120 selected from a thermistor, a bimetal, and a semiconductor device.

An electrical path formed by the battery cell (BAT) and the external circuit 125 may be a closed loop, and a current flowing through the closed loop may be inversely proportional to an equivalent resistance of the battery cell (BAT) and an equivalent resistance of the external circuit 125. As the equivalent resistance of the external circuit 125 becomes smaller, the current flowing through the closed loop may become greater, and the short-circuit current in the battery cell (BAT) may further increase.

When the equivalent resistance of the external circuit 125 is greater than a reference resistance, the external circuit 125 may be close to a state in which both ends of the external circuit 125 are electrically disconnected. When the equivalent resistance of the external circuit 125 is smaller than the reference resistance, the external circuit 125 may be close to a state in which both the ends of the external circuit 125 are electrically connected.

When both the ends of the external circuit 125 are electrically disconnected, a closed loop through which the short-circuit current flows in the battery cell (BAT) may not be substantially formed. When both the ends of the external circuit 125 are electrically connected, the closed loop through which the short-circuit current flows in the battery cell (BAT) may then be formed, thus further increasing the short-circuit current.

Referring to FIGS. 2A and 3B, the external circuit 125 may include a thermistor 120a or a bimetal, and the forming of the state may include changing a temperature of thermistor 120a or the bimetal. For example, when the thermistor 120a is a negative temperature coefficient (NTC) thermistor, a resistance of the thermistor 120a may decrease as the temperature of thermistor 120a increases, and the short-circuit current in the battery cell (BAT) may further increase.

For example, the bimetal may be implemented as a bimetal switch. The bimetal switch may be switched from an on state (i.e., an electrically connected state between both ends) to an off state (i.e., an electrically disconnected state between both the ends) or from the off state to the on state when temperature is higher than a reference temperature, and the short-circuit current in the battery cell (BAT) may further increase.

For example, changing (e.g., heating) the temperature of the thermistor 120a or the bimetal may be implemented to simulate a situation in which an actual battery cell temperature increases. Accordingly, the method for inspecting an internal short in a battery cell and the measurement battery cell (BAT) according to an embodiment of the present disclosure may also be used to inspect electrical safety based on heat occurrence in the battery cell (BAT).

For example, when the temperature of the thermistor 120a or the bimetal is changed (e.g., heated), a temperature of the battery cell (BAT) may be substantially maintained. Accordingly, in a process of inspecting the electrical safety based on heat occurrence in the battery cell (BAT), the battery cell (BAT) may be prevented from being damaged by heat. For example, the thermistor 120a or the bimetal may be heated while being spaced apart from the battery cell (BAT) or may be independently accommodated in a heating chamber.

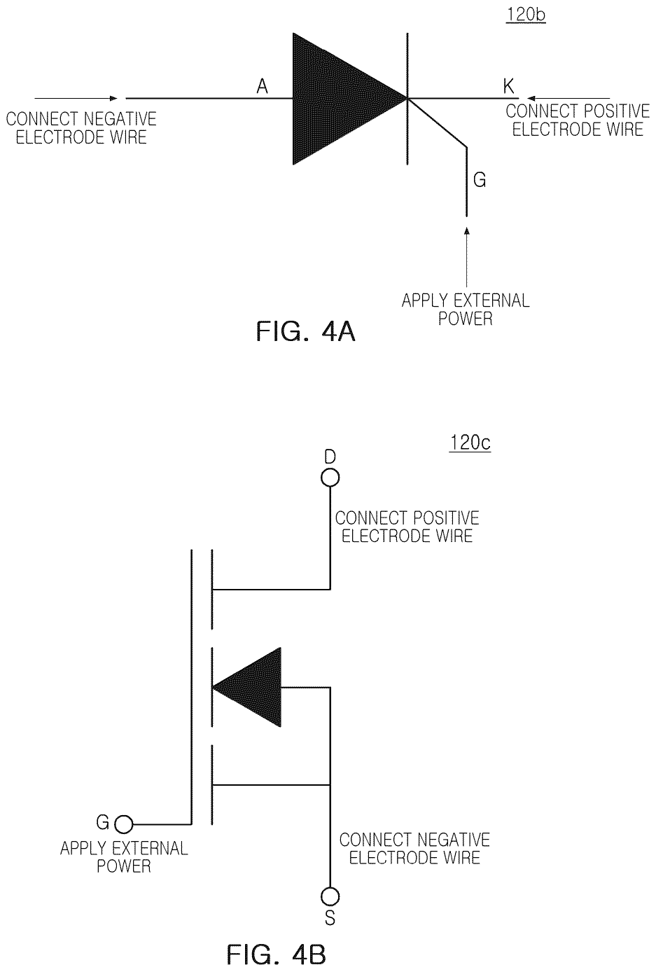

Referring to FIGS. 2A, 4A, and 4B, the external circuit 125 may include semiconductor devices 120b and 120c, and the forming of the state may include applying external power to the semiconductor devices 120b and 120c. For example, the semiconductor device 120b may be a thyristor, and the semiconductor device 120c may be a transistor (e.g., a metal-oxide-semiconductor field-effect transistor (MOSFET)). The semiconductor devices 120b and 120c may each be switched from an off state (disconnected between a negative electrode wire and a positive electrode wire) to an on state (connected between the positive electrode wire and the negative electrode wire) by receiving external power, and the short-circuit current in the battery cell (BAT) may further increase.

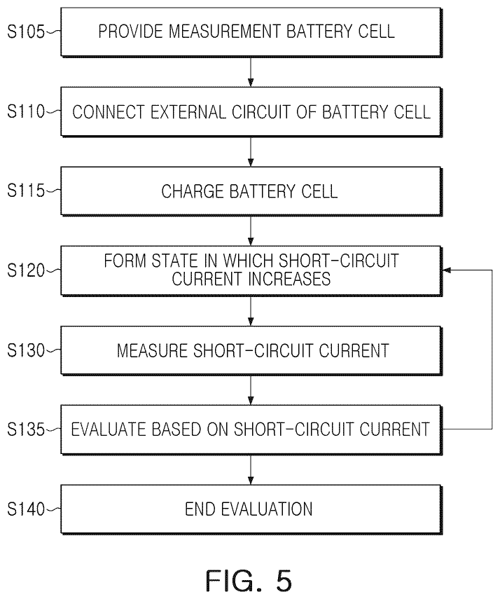

Referring to FIGS. 3A, 3B, and 5, the method for inspecting an internal short in a battery cell according to an embodiment of the present disclosure may further include providing the battery cell by inserting a portion of the measurement electrode 21 into the battery cell to have a portion of the measurement electrode 21 overlapping the positive electrode plate 11C and negative electrode plate 12C of the battery cell in the direction (e.g., the vertical direction) in which the positive electrode plate 11C and the negative electrode plate 12C face each other (S105), and may then further include charging the battery cell (e.g., to 100% state of charge) (S115).

The direction in which the positive electrode plate 11C and the negative electrode plate 12C face each other may be substantially the same as a direction in which the short-circuit current flows between the positive electrode plate 11C and the negative electrode plate 12C, and the measurement electrode 21 may thus efficiently trigger the short-circuit current in the direction overlapping the positive electrode plate 11C and the negative electrode plate 12C.

For example, the measurement electrode 21 may be formed in a plate shape and may have a narrow width (e.g., a shape close to a line). For example, a portion of the measurement electrode 21 may be disposed between the positive electrode plate 11C and the negative electrode plate 12C, and may be disposed between the negative electrode plate 12C and the separator 13. For example, a horizontal length of the measurement electrode 21 may be shorter than a horizontal length of each of the positive electrode plate 11C and the negative electrode plate 12C.

For example, another portion of the measurement electrode 21 may not be accommodated in the outer member 10 and protrude from the outer member 10, and may have a structure (e.g., a connector structure) that may be coupled to the wire 110.

Referring to FIGS. 2A and 5, the apparatus for determining an internal short in a battery cell according to an embodiment of the present disclosure may include a measuring instrument 130 for measuring the short-circuit current between the positive electrode plate and negative electrode plate of the measurement battery cell (BAT) through the measurement electrode 21. The measuring (S130) may include generating short-circuit current evaluation information of the battery cell based on a difference between a pattern (e.g., a slope, an average value, or a critical point) of the measured short-circuit current and a reference pattern (S135). Depending on whether there is an additional battery cell to be inspected, an internal short in the additional battery cell may then be inspected or the evaluation may be terminated (S140).

For example, the measuring instrument 130 may include a measurement circuit (e.g., a sampling circuit, a buffer circuit, an amplification circuit, or an analog-to-digital conversion circuit) such as a digital multi meter, and may include a controller for generating the short-circuit current evaluation information. The controller may be implemented as a computing system (e.g., a processor, a memory, a recording medium, an input/output device, or a communication device) such as a microcontroller, may be at least a portion of a manufacturing execution system (MES), or may be linked to the MES through the communication device.

FIG. 2A illustrates that the measuring instrument 130 is directly connected to the wire 110. However, depending on design, the measuring instrument 130 may not be directly connected to the wire 110 and measure the short-circuit current in a non-contact manner (e.g., by sensing a magnetic field through a Hall sensor to measure the current).

For example, the controller of the measuring instrument 130 may store a pattern of the short-circuit current measured for a good battery cell as the reference pattern, may determine (e.g., generate values through calculation and generate determination information through comparison between the values) whether a difference (e.g., a slope difference, an average value difference, a critical point difference) between a pattern of the current measured for another battery cell and the reference pattern exceeds an error range, may generate information indicating that the corresponding battery cell has a defect when the error range is exceeded, and may generate information indicating that the corresponding battery cell is a good product when the difference does not exceed the error range.

For example, the controller of the measuring instrument 130 may convert the measured short-circuit current into Joule heat and may generate temperature safety evaluation information of the battery cell based on the Joule heat.

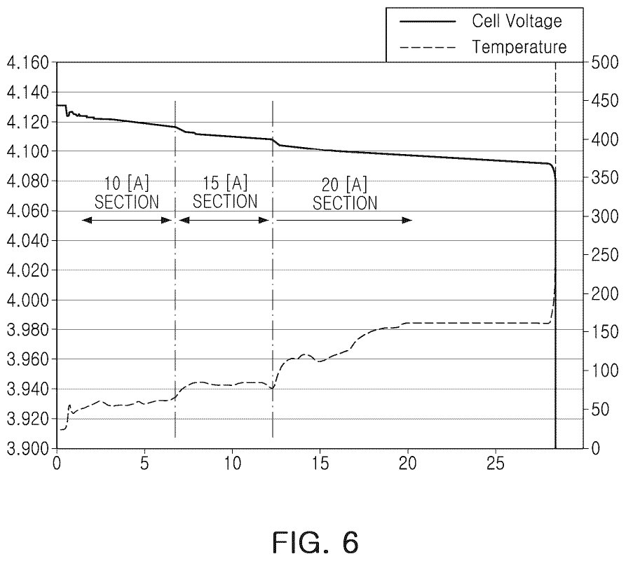

FIG. 6 is a graph illustrating a voltage (cell voltage) and a temperature according to a time flow from a time point (zero minutes) at which semiconductor devices 120b and 120c (see FIGS. 4A and 4B) are each switched from an off state to an on state. A horizontal axis of FIG. 6 represents time (unit: minute), a left side of a vertical axis of FIG. 6 represents the voltage (cell voltage) (unit: V) between the measurement electrode 21 (see FIG. 2A) and an electrode lead 14 (see FIG. 2A), and a right side of the vertical axis of FIG. 6 represents a temperature (unit: Celsius) of the battery cell. FIG. 6 illustrates experimental data obtained by configuring the semiconductor device as a metal-oxide-semiconductor field-effect transistor (MOSFET). However, the semiconductor device is not limited to the MOSFET and may be replaced with a thermistor or a bimetal switch depending on design.

As the short-circuit current continuously flows, an internal structure of the battery cell may change (e.g., a distance between the positive electrode plate and the negative electrode plate becoming smaller) to have a larger short-circuit current. Accordingly, as time passes, the short-circuit current may gradually increase (e.g., increase from less than 10 amperes (A) to more than 20 amperes (A)), the voltage (cell voltage) may gradually decrease, and the temperature may gradually increase. A pattern (e.g., a slope or an average value) of the short-circuit current measured by the measuring instrument 130 (see FIG. 2A) during this period may be used to determine whether the battery cell has a defect (e.g., a defect in short-circuit current characteristics).

When the short-circuit current becomes excessively large (approximately 28 minutes in FIG. 6), the temperature may rapidly increase due to thermal runaway of the battery cell, and the voltage (cell voltage) may rapidly decrease. The pattern (e.g., a critical time point and/or a critical current at which the short-circuit current rapidly changes) of the short-circuit current measured by the measuring instrument 130 (see FIG. 2A) during this period may be used to determine whether the battery cell has a defect (e.g., a defect in short-circuit current characteristics).

As set forth above, the method and the apparatus for inspecting an internal short in a battery cell and the measurement battery cell according to an embodiment of the present disclosure may reduce inspection condition deviations among a plurality of battery cells, thereby improving the reliability of internal short inspection of the battery cell.

Only specific examples of implementations of certain embodiments are described. Variations, improvements and enhancements of the disclosed embodiments and other embodiments may be made based on the disclosure of this patent document.

What is claimed is:

1. A method for inspecting an internal short in a battery cell, the method comprising:
forming a state in which a short-circuit current in the battery cell increases through an external circuit of the battery cell connected to a measurement electrode, with inserting a portion of the measurement electrode into the battery cell through an outer member of the battery cell; and
measuring the short-circuit current through the external circuit.

2. The method of claim 1, in which the external circuit includes a thermistor or a bimetal,
wherein the forming of the state includes changing a temperature of the thermistor or the bimetal.

3. The method of claim 1, in which the external circuit includes a semiconductor device,
wherein the forming of the state includes applying external power to the semiconductor device.

4. The method of claim 1, wherein the forming of the state includes connecting a wire to a connector disposed on an electrode lead of the battery cell and the measurement electrode.

5. The method of claim 4, in which the battery cell includes an encapsulating member encapsulating at least one of the connector or the measurement electrode,
wherein the forming of the state includes inserting the wire into the encapsulating member or removing a portion of the encapsulating member, so as to connect the wire to the connector and the measurement electrode.

6. The method of claim 1, wherein the forming of the state includes connecting the external circuit between the measurement electrode connected to an outermost negative electrode plate among a plurality of negative electrode plates of the battery cell and an electrode lead of the battery cell connected to a positive electrode plate of the battery cell.

7. The method of claim 1, further comprising:
providing the battery cell by inserting a portion of the measurement electrode into the battery cell to have a portion of the measurement electrode overlapping a positive electrode plate and a negative electrode plate in a direction in which the positive electrode plate and the negative electrode plate of the battery cell face each other.

8. The method of claim 1, wherein the measuring includes generating short-circuit current evaluation information of the battery cell based on a difference between a pattern of the measured short-circuit current and a reference pattern.

9. A measurement battery cell comprising:
an outer member;
a positive electrode plate accommodated in the outer member;
a negative electrode plate accommodated in the outer member;
a separator disposed between the positive electrode plate and the negative electrode plate;
an electrode lead connected to one of the positive electrode plate and the negative electrode plate and protruding from the outer member; and
a measurement electrode penetrating the outer member to have a portion thereof overlapping the positive electrode plate and the negative electrode plate in a direction in which the positive electrode plate and the negative electrode plate face each other.

10. The measurement battery cell of claim 9, wherein the measurement electrode is connected to only one of the positive electrode plate and the negative electrode plate.

11. The measurement battery cell of claim 10, wherein the negative electrode plate is provided as a plurality of negative electrode plates,
the measurement electrode is connected to an outermost negative electrode plate among the plurality of negative electrode plates, and
the electrode lead is connected to the positive electrode plate.

12. The measurement battery cell of claim 9, further comprising:
an encapsulating member encapsulating the measurement electrode.

13. The measurement battery cell of claim 12, further comprising:
a connector disposed on the electrode lead and encapsulated by the encapsulating member.

14. An apparatus for inspecting an internal short in a battery cell, the apparatus comprising:
a measuring instrument for measuring a short-circuit current between a positive electrode plate and a negative electrode plate of a measurement battery cell through measurement electrode;
a wire connected to an electrode lead of the measurement battery cell and the measurement electrode; and
an external circuit electrically connected between the electrode lead and the measurement electrode through the wire.

15. The apparatus of claim 14, wherein the measurement battery cell includes:
an outer member;
the positive electrode plate accommodated in the outer member;
the negative electrode plate accommodated in the outer member;
a separator disposed between the positive electrode plate and the negative electrode plate;
the electrode lead connected to one of the positive electrode plate and the negative electrode plate and protruding from the outer member; and
the measurement electrode penetrating the outer member to have a portion thereof overlapping the positive electrode plate and the negative electrode plate in a direction in which the positive electrode plate and the negative electrode plate face each other.

16. The apparatus of claim 15, wherein the measurement electrode is connected to only one of the positive electrode plate and the negative electrode plate.

17. The apparatus of claim 16, wherein the negative electrode plate is provided as a plurality of negative electrode plates,
the measurement electrode is connected to an outermost negative electrode plate among the plurality of negative electrode plates, and
the electrode lead is connected to the positive electrode plate.

18. The apparatus of claim 15, wherein the measurement battery cell further includes an encapsulating member encapsulating the measurement electrode.

19. The apparatus of claim 18, wherein the measurement battery cell further includes a connector disposed on the electrode lead and encapsulated by the encapsulating member.

20. The apparatus of claim 14, wherein the external circuit includes at least one of a thermistor, a bimetal, or a metal-oxide-semiconductor field-effect transistor (MOSFET).
